(19) United States
(12) Patent Application Publication
(10) Pub. No.: US 2009/0160557 A1
(43) Pub. Date: Jun. 25, 2009

(54) SELF-BIASED CASCODE CURRENT MIRROR

(75) Inventors: RAIMONDO LUZZI, Graz (AT); Marco Bucci, Graz (AT); Alessandro Trifiletti, Velletri (IT)

Correspondence Address: DICKSTEIN SHAPIRO LLP, 1177 AVENUE OF THE AMERICAS 6TH AVENUE, NEW YORK, NY, 10036-2714, US

(73) Assignee: Infineon Technologies AG, Neubiberg (DE)

(21) Appl. No.: 11/961,423

(22) Filed: Dec. 20, 2007

(51) Int. Cl. H03F 3/04

(52) U.S. Cl. 330/288

(57) ABSTRACT

A self-biased cascode current mirror circuit, including a first transistor having a first current electrode, a control electrode, and a second current electrode; a second transistor having a first current electrode coupled to the second current electrode of the first transistor, a control electrode coupled to the first current electrode of the first transistor, and a second current electrode coupled to a terminal; a third transistor having a first current electrode configured to provide an output current, a control electrode coupled to the control electrode of the first transistor and the first current electrode of the third transistor, and a second current electrode; and a fourth transistor having a first current electrode coupled to the second current electrode of the third transistor, a control electrode coupled to the control electrode of the second transistor, and a second current electrode coupled to the terminal.

### FIELD OF THE INVENTION

The present invention relates to devices for producing or processing currents, and more particularly to the variety of such devices commonly referred to as current mirrors.

### BACKGROUND OF THE INVENTION

In the field of transistorized current sources, it has been a general practice to employ current mirrors as current sources. Current mirrors have also been used to mirror a varying input signal current.

A current mirror receives an input current into one node, typically a low impedance node, and produces an output current at another node. That output current is a direct function (such as a reproduction or linear scaling) of the input current. In some cases, multiple (equal or unequal) currents are produced for distribution to different output nodes. Increased output resistance and increased effective open circuit voltage can be obtained by a multiple cascode current mirror configuration. An alternative configuration is the Wilson current source, which utilizes negative feedback in lieu of a cascode configuration. Each of these current mirrors requires additional circuitry in the form of an additional branch to generate a gate bias for proper operation.

### SUMMARY OF THE INVENTION

A self-biased cascode current mirror circuit, including a first transistor having a first current electrode, a control electrode, and a second current electrode; a second transistor having a first current electrode coupled to the second current electrode of the first transistor, a control electrode coupled to the first current electrode of the first transistor, and a second current electrode coupled to a terminal; a third transistor having a first current electrode configured to provide an output current, a control electrode coupled to the control electrode of the first transistor and the first current electrode of the third transistor, and a second current electrode; and a fourth transistor having a first current electrode coupled to the second current electrode of the third transistor, a control electrode coupled to the control electrode of the second transistor, and a second current electrode coupled to the terminal.

### BRIEF DESCRIPTION OF THE DRAWINGS

FIG. 1 is diagram of a cascode current mirror according to an embodiment of the present invention;

FIG. 2 is a graph showing the output characteristics of the cascode current mirror of FIG. 1;

FIG. 3A is a diagram of a folded cascode operational transconductance amplifier according to an embodiment of the present invention;

FIG. 3B is an equivalent diagram for the diagram shown in FIG. 3A;

FIG. 3C is the DC characteristic of the unit gain folded cascode operational transconductance amplifier shown in FIG. 3A;

FIG. 4A is a diagram of the current mirror used as active load in a comparator according to an embodiment of the present invention;

FIG. 4B is an equivalent diagram for the diagram shown in FIG. 4A; and

FIG. 4C is the DC characteristic of the comparator shown in FIG. 4A.

### DETAILED DESCRIPTION OF THE PREFERRED EMBODIMENTS

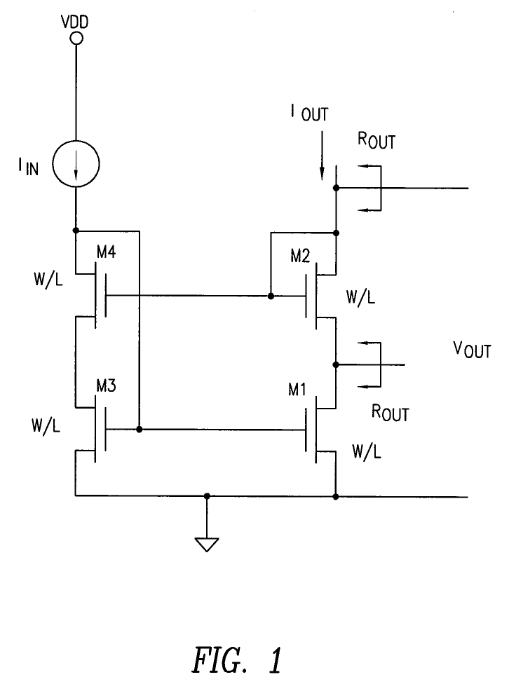

FIG. 1 is a diagram of a self-biased cascode current mirror having a small signal output impedance equal to what can be obtained using a cascode current mirror, without requiring an additional external bias branch. The circuit of FIG. 1 does not draw additional current for a biasing branch.

As shown in FIG. 1, MOS transistor M4 receives a current IIN at its source. The drain of MOS transistor M4 is connected to the source of MOS transistor M3. The drain of MOS transistor M3, as shown in this embodiment, is connected to ground. The source of MOS transistor M4 is connected to the gate of MOS transistor M3. The gate of MOS transistor M2 is connected to the gate of MOS transistor M4. Likewise, the gate of MOS transistor M1 is connected to the gate of MOS transistor M3. The source of MOS transistor M2 is connected to the drain of MOS transistor M1 and the source of MOS transistor M1 is connected to ground. Finally, the drain of MOS transistor M2 is connected to its gate. In this manner, MOS transistor M4 is biased by the diode connected MOS transistor M2. Transistors M1-M4 can be bipolar transistors, field effect transistors, N-channel transistors, P-channel transistors, or a combination thereof. Each of the MOS transistors M1-M4 operates in the active region for Vout>Vt+2Vov, where Vt is the threshold voltage and Vov is the overdrive voltage. For Vout>2 Vt+Vov, MOS transistor M4 operates in the triode region.

The diode connection of MOS transistor M2 of FIG. 1 closes a feedback loop thereby increasing the output impedance Rout. Namely, as Vout increases, the drain voltage of MOS transistor M3 increases as well. The increase of Vout results in an increase of the source voltage of MOS transistor M3 which in turn, since Iin is constant, results in a corresponding decrease of VgsM1 that equals VgsM2 thereby counteracting the increase of Iout. Further, because Iin is constant, MOS transistor M3's gate-source voltage decreases thereby counteracting the increase of the output current Iout.

A small signal analysis of the circuit of FIG. 1 reveals that Rout □ gmro2, similar to a biased cascode current mirror, where gm is the transconductance and ro is the small signal output impedance. It should be noted that the same small signal resistance is seen looking into the drain of MOS transistor M1 or M2. In the situation that Vout>2Vt+Vov, MOS transistor M3 operates in the triode region and the circuit behaves as a simple current mirror where the output voltage is dictated by M4.

In order to assess the precision of the current mirroring, an expression for Iout-Iin is derived assuming equal sized transistors and neglecting the finite output resistance of M3, M4. For the input branch, where Iin is the input current, β is the current gain, and λ is the channel length modulation, it holds that

$${I}_{in} = \frac{β}{2} {V}_{ov 1}^{2} ( 1 + λ {V}_{out} - λ {V}_{gs 3} ) \\ where \\ {V}_{ov 1} = {V}_{gs 1} + {V}_{t} , and {V}_{gs 3} = {V}_{t} + \sqrt{2 {I}_{in} / β} . \qquad ( 1 )$$

Similarly, the output current is given by

$${I}_{out} = \frac{β}{2} {V}_{ov 2}^{2} ( 1 + λ {V}_{out} λ {V}_{gs 4} ) \\ where \\ {V}_{ov 2} = {V}_{ov 1} , and {V}_{gs 4} = {V}_{t} + \sqrt{2 {I}_{out} / β} . \qquad ( 2 )$$

Deriving V²ₒᵥ₁ from (1), and substituting in (2), it follows that

$${I}_{out} = {I}_{in} \frac{{V}_{out} - {V}_{t} + {V}_{a} + \sqrt{2 {I}_{out} / β}}{{V}_{out} - {V}_{t} + {V}_{a} - \sqrt{2 {I}_{in} / β}} \\ where {V}_{a} = 1 / λ . \qquad ( 3 )$$

Finally, solving with respect to \sqrt{Iₒᵤₜ}, it results that

$$\sqrt{{I}_{out}} = \frac{( {V}_{out} {V}_{t} + {V}_{a} ) \sqrt{{I}_{in}}}{( {V}_{out} {V}_{t} + {V}_{a} ) \sqrt{2 {I}_{in} / β}} \qquad ( 4 )$$

valid for Vₜ+2Vₒᵥ<Vₒᵤₜ<2Vₜ+Vₒᵥ.

In one embodiment of the diagram of FIG. 1, typical process and circuit parameter values are listed in Table 1 below. Based on the values in Table 1, equation (4) predicts a systematic gain error of approximately 0.5%.

TABLE 1

| Parameter | Value | Unit |
|---|---|---|
| K′ | 200 | μA/V² |
| V_{A} | 7 | V |
| Vₜ | 0.5 | V |
| W/L | 25 | — |
| Iᵢₙ | 1 | μA |
| Vₒᵤₜ | 1 | V |

An AC analysis of the circuit of FIG. 1 results in the following expression for the output resistance:

$${R}_{out} = \frac{{g}_{m}^{3}}{{g}_{m}^{2} \frac{1}{{r}_{o}^{2}} + 2 {g}_{m} \frac{1}{{r}_{o}^{3}} + \frac{1}{{r}_{o}^{4}}}$$

Neglecting the negligible terms

$$\frac{1}{{r}_{o}^{3}} and \frac{1}{{r}_{o}^{4}} ,$$

it holds that Rₒᵤₜ≅gₘr₀², as expected in a cascode current mirror. As mentioned above, the same output resistance is seen looking into the drain of MOS transistor M2.

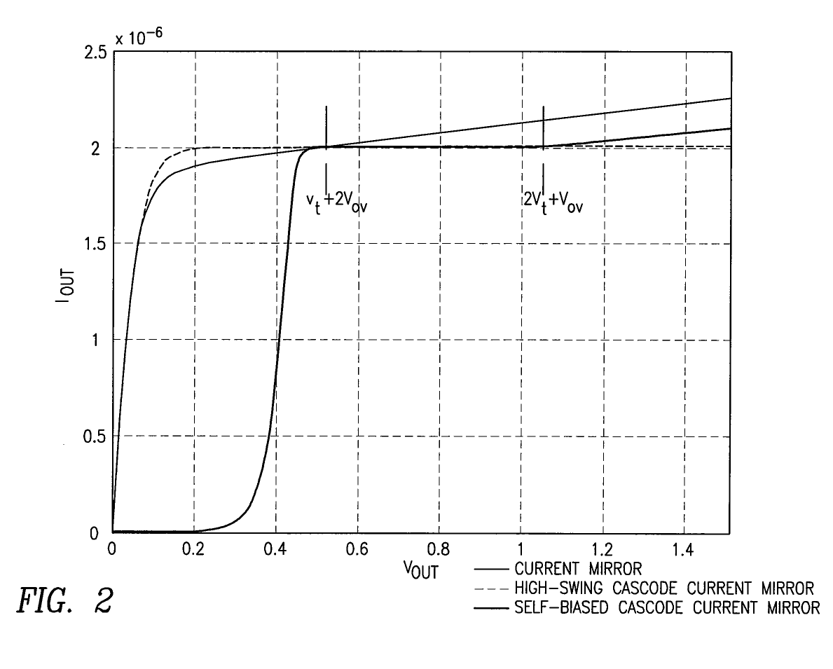

A simulated Vₒᵤₜ-Iₒᵤₜ characteristic is shown in FIG. 2, where a simple current mirror, a high-swing cascode current mirror, and the self-biased current mirror of FIG. 1 are compared. For Vₒᵤₜ>2Vₜ+Vₒᵥ, every transistor in the circuit of FIG. 1 is in the active region and the self-biased cascode current mirror has substantially the same output resistance as a high-swing cascode current mirror. As shown, when MOS transistors M1-M4 are in the active region, the output current Iₒᵤₜ is substantially constant. Once Vₒᵤₜ>2Vₜ+Vₒᵥ, MOS transistor M4 operates in the triode region, the output resistance decreases to that of a simple current mirror, and Iₒᵤₜ increases substantially parallel to the output of the simple current mirror. Therefore, in applications where a large dynamic range is not required, the diagram of FIG. 1 can be used as an active load for high gain amplifiers because the current required to bias standard current mirrors is not necessary.

It should be noted that the self-biased current mirror disclosed above can be used in any application in which a current mirror is required. Such applications include operational transconductance amplifiers and voltage comparators.

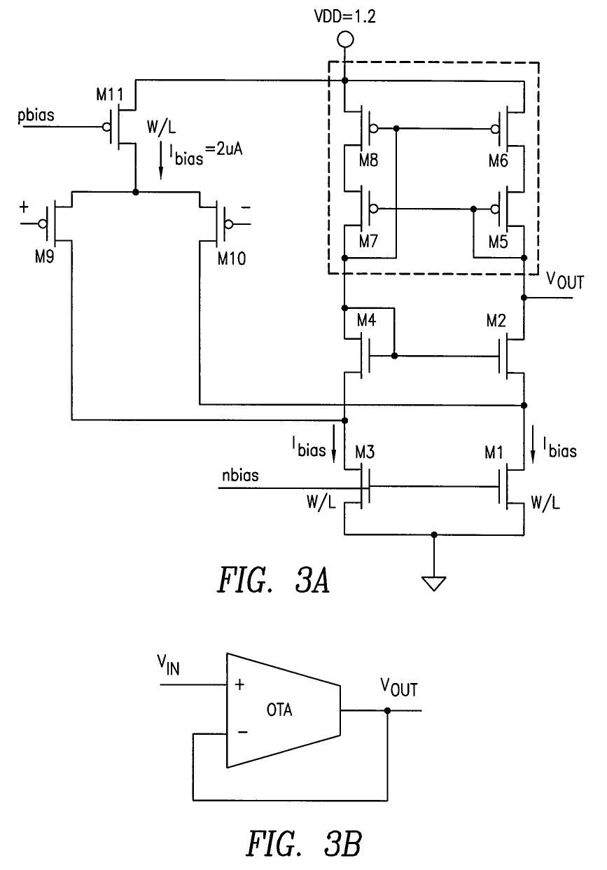

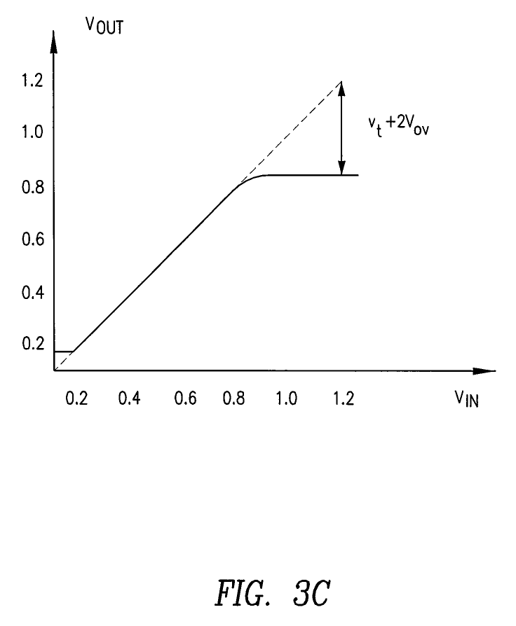

FIG. 3A is a diagram of a folded cascode operational transconductance amplifier including a self-biased current mirror (shown within the gray box) according to an embodiment of the present invention. An open loop gain greater than 70 dB can be obtained for Vout over the output range specified in FIG. 2. A typical application is a buffer for reference voltages around VDD/2. Since the bias voltages pbias/nbias would be likely already available in the chip, the circuit does not require additional biasing circuitry. FIG. 3B is an equivalent diagram for the diagram shown in FIG. 3A. FIG. 3C shows the DC characteristic of the unit gain folded cascode operational transconductance amplifier of FIG. 3A. The actual operation of the circuit shown in FIG. 3A is beyond the scope of this disclosure and will therefore not be addressed herein.

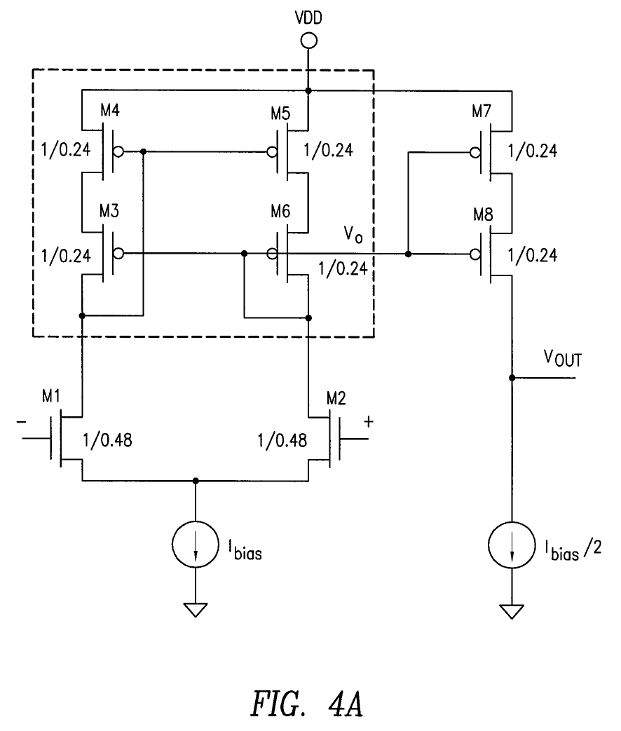

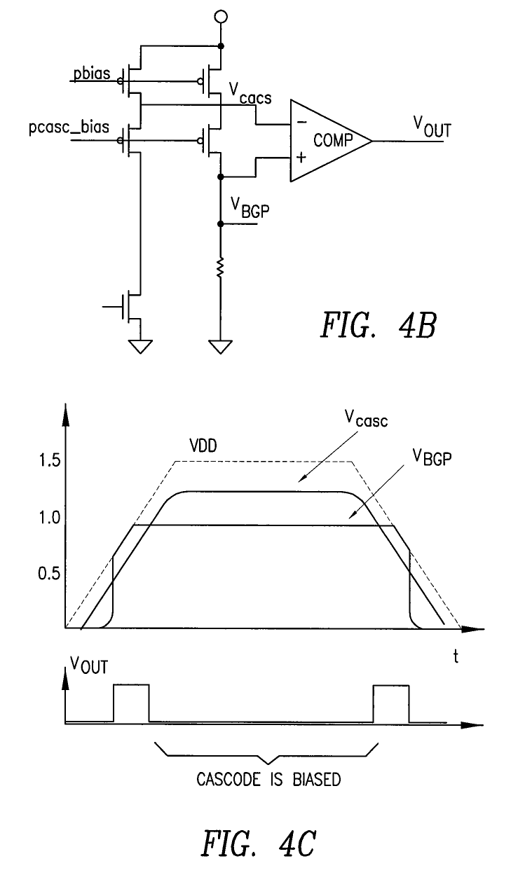

FIG. 4A is a diagram a comparator circuit that utilizes the current mirror of FIG. 1 (shown within the gray box) as an active load. The comparator circuit has a fast commutation time and low power consumption. Since the output of the first stage (node Vo) does not saturate to VDD, the 0-to-1 commutation time is reduced. This circuit is useful for detecting a valid reference voltage (VBGP) during power-up/down. FIG. 4C is the DC characteristic of the comparator shown in FIG. 4A. The actual operation of the circuit shown in FIG. 4A is beyond the scope of this disclosure and will therefore not be addressed herein.

Having thus described at least illustrative embodiments of the invention, various modifications and improvements will readily occur to those skilled in the art and are intended to be within the scope of the invention. Accordingly, the foregoing description is by way of example only and is not intended as limiting. The invention is limited only as defined in the following claims and the equivalents thereto.

What is claimed is:

1. A self-biased cascode current mirror circuit, comprising:
a first transistor having a first current electrode, a control electrode, and a second current electrode;
a second transistor having a first current electrode coupled to the second current electrode of the first transistor, a control electrode coupled to the first current electrode of the first transistor, and a second current electrode coupled to a terminal;
a third transistor having a first current electrode configured to provide an output current, a control electrode coupled to the control electrode of the first transistor and the first current electrode of the third transistor, and a second current electrode; and
a fourth transistor having a first current electrode coupled to the second current electrode of the third transistor, a control electrode coupled to the control electrode of the second transistor, and a second current electrode coupled to the terminal.

2. The self-biased cascode current mirror of claim 1, wherein said first, second, third, and fourth transistors are metal oxide semiconductor field effect transistors.

3. The self-biased cascode current mirror of claim 1, wherein said first, second, third, and fourth transistors are N-channel transistors.

4. The self-biased cascode current mirror of claim 1, wherein said first, second, third, and fourth transistors are P-channel transistors.

5. The self-biased cascode current mirror of claim 1, wherein the terminal is coupled to ground.

6. The self-biased cascode current mirror of claim 1, wherein the terminal is coupled to VDD.

7. The self-biased cascode current mirror of claim 1, wherein the current output for Vₜ+2Vₒᵥ<Vₒᵤₜ<2Vₜ+Vₒᵥ is substantially linear, wherein Vₜ is the threshold voltage and Vₒᵥ is the overdrive voltage.

8. The self-biased cascode current mirror of claim 1, wherein for Vₒᵤₜ>2Vₜ+Vₒᵥ the third transistor is operating in the triode region, wherein Vₜ is the threshold voltage and Vₒᵥ is the overdrive voltage.

9. The self-biased cascode current mirror of claim 1, wherein for Vₜ+2Vₒᵥ<Vₒᵤₜ<2Vₜ+Vₒᵥ the first, second, third, and forth transistors are operating in their active region, wherein Vₜ is the threshold voltage and Vₒᵥ is the overdrive voltage.

10. A folded cascode operational transconductance amplifier comprising the self-biased cascode current mirror of claim 1.

11. A comparator circuit comprising the self-biased cascode current mirror of claim 1.

12. The comparator circuit of claim 11, wherein the self-biased cascode current mirror is an active load.

13. The comparator circuit of claim 12, wherein an output of a first stage does not saturate to VDD.

14. The comparator circuit of claim 13 configured to detect a valid voltage reference voltage.
